(19) United States
(12) Patent Application Publication
(10) Pub. No.: US 2025/0293141 A1
(43) Pub. Date: Sep. 18, 2025

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventors: Kyungseon Hwang, Suwon-si (KR); Baek KI, Suwon-si (KR)

(21) Appl. No.: 18/985,914

(22) Filed: Dec. 18, 2024

(30) Foreign Application Priority Data
Dec. 21, 2023 (KR) 10-2023-0188793

(51) Int. Cl. H01L 23/498; H01L 23/00

(52) U.S. Cl. CPC H01L 23/49838; H01L 23/49822; H01L 24/16; H01L 24/73; H01L 2224/16227; H01L 2224/73204; H01L 2924/1511

(57) ABSTRACT

Provided is a package substrate including a body including at least one insulating layer stacked in a vertical direction and wiring patterns located in the insulating layer, an upper solder resist layer covering an upper surface of the body, and a lower solder resist layer covering a lower surface of the body, wherein the upper surface of the body is sealed by the upper solder resist layer, and at least a portion of the lower surface of the body is exposed downward from the lower solder resist layer in the vertical direction through a recess formed in the lower solder resist layer.

### CROSS-REFERENCE TO RELATED APPLICATION

This application is based on and claims priority under 35 U.S.C. § 119 to Korean Patent Application No. 10-2023-0188793, filed on Dec. 21, 2023, in the Korean Intellectual Property Office, the disclosure of which is incorporated by reference herein in its entirety.

### BACKGROUND

The inventive concept relates to a package substrate and a semiconductor package including the same, and more particularly, to a package substrate including solder resist, and a semiconductor package including the package substrate.

Recently, in the electronic product market, demand for portable devices is rapidly increasing. As a result, there is a continuous need for smaller and lighter electronic components mounted in the electronic products. To manufacture the smaller and lighter electronic components, semiconductor packages mounted therein are required to process high amounts of data while becoming smaller in volume.

In a package substrate on which a semiconductor chip is mounted, solder resist is applied to the surface of the package substrate to insulate and protect the surface thereof from abrasion, heat, and moisture.

Meanwhile, when bonding the semiconductor chip to the package substrate, the package substrate is exposed to a high temperature and high pressure environment. The warpage of the package substrate may occur due to differences in thermal expansion coefficients of various layers of the package substrate, asymmetric distribution of solder resist, and temperature changes accompanying the production process.

### SUMMARY

The inventive concept provides a package substrate with improved structural reliability, and a semiconductor package including the same.

In addition, the inventive concept is not limited to that above, and other inventive concepts not mentioned are clearly understood by those skilled in the art from the description below.

According to an aspect of the inventive concept, there is provided
a package substrate including a body including at least one insulating layer stacked in a vertical direction and wiring patterns located in the insulating layer, an upper solder resist layer covering an upper surface of the body, and a lower solder resist layer covering a lower surface of the body, wherein the upper surface of the body is sealed by the upper solder resist layer, and at least a portion of the lower surface of the body is exposed downward from the lower solder resist layer in the vertical direction through a recess formed in the lower solder resist layer.

According to another aspect of the inventive concept, there is provided
a semiconductor package including a package substrate, a semiconductor chip positioned on the package substrate, and a bump positioned between the package substrate and the semiconductor chip, wherein the package substrate includes a body including at least one insulating layer stacked in a vertical direction and wiring patterns located in the insulating layer, an upper solder resist layer covering an upper surface of the body, and a lower solder resist layer covering a lower surface of the body, the upper surface of the body is sealed by the upper solder resist layer, and the lower solder resist layer has a recess that extends in the vertical direction.

According to another aspect of the inventive concept, there is provided a semiconductor package including a package substrate, a semiconductor chip positioned on the package substrate, and a bump positioned between the package substrate and the semiconductor chip, wherein the package substrate includes a body including at least one insulating layer stacked in a vertical direction and wiring patterns located in the insulating layer, an upper substrate pad located on an upper surface of the body, a lower substrate pad located on a lower surface of the body, an upper solder resist layer covering the upper surface of the body, and a lower solder resist layer covering the lower surface of the body, wherein the lower solder resist layer includes a unit area that overlaps with the lower substrate pad in the vertical direction, and a dummy area that does not overlap with the lower substrate pad in the vertical direction, and the upper surface of the body is sealed by the upper solder resist layer, and the lower solder resist layer has a recess extending in the vertical direction, the recess is formed in the dummy area, and the cross-section of the recess in the X-Y plane has a longitudinal direction parallel to a short axis of the body.

### BRIEF DESCRIPTION OF THE DRAWINGS

Embodiments will be more clearly understood from the following detailed description taken in conjunction with the accompanying drawings in which:

FIG. 1 is a cross-sectional view of a package substrate according to some embodiments;

FIG. 2 is a schematic plan view of the package substrate of FIG. 1;

FIG. 3 is a schematic bottom view of the package substrate of FIG. 1;

FIGS. 4 and 5 are cross-sectional views illustrating the warpage of the package substrate of FIG. 1;

FIG. 6 is a schematic cross-sectional view of a package substrate according to some embodiments;

FIG. 7 is a schematic cross-sectional view of a package substrate according to some embodiments;

FIG. 8 is a schematic bottom view of a package substrate according to some embodiments;

FIG. 9 is a schematic cross-sectional view of a semiconductor package according to some embodiments; and

FIGS. 10A, 10B, 10C and 10D show alternative configurations for the recesses.

### DETAILED DESCRIPTION OF THE EMBODIMENTS

Hereinafter, embodiments are described in detail with reference to the accompanying drawings. The same reference numerals are used for the same components in the drawings, and overlapping descriptions thereof are omitted.

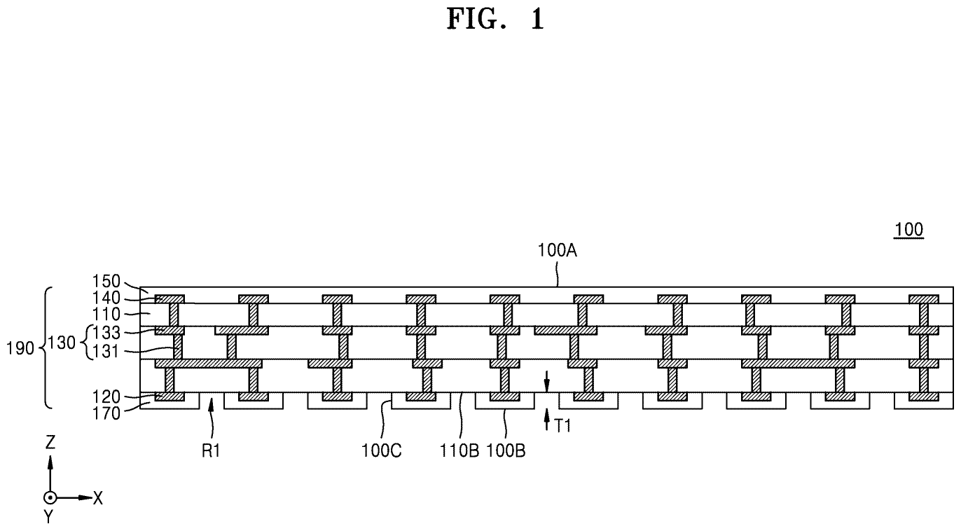

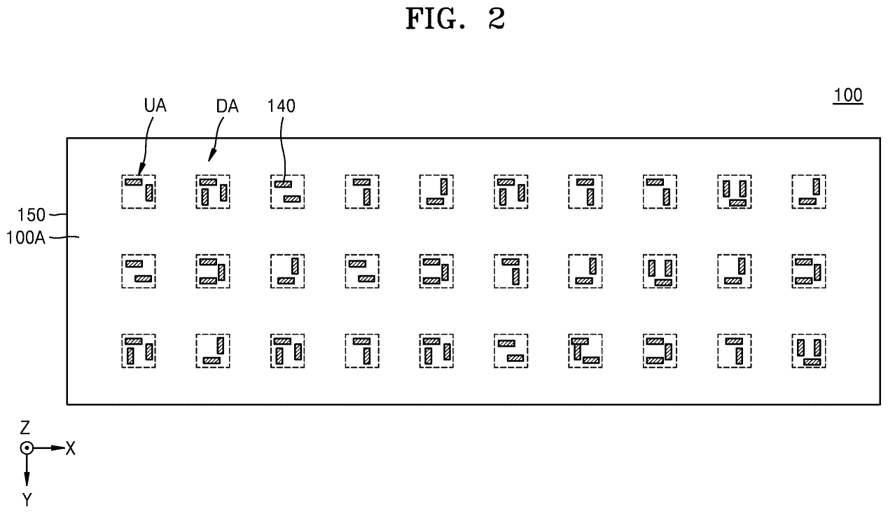

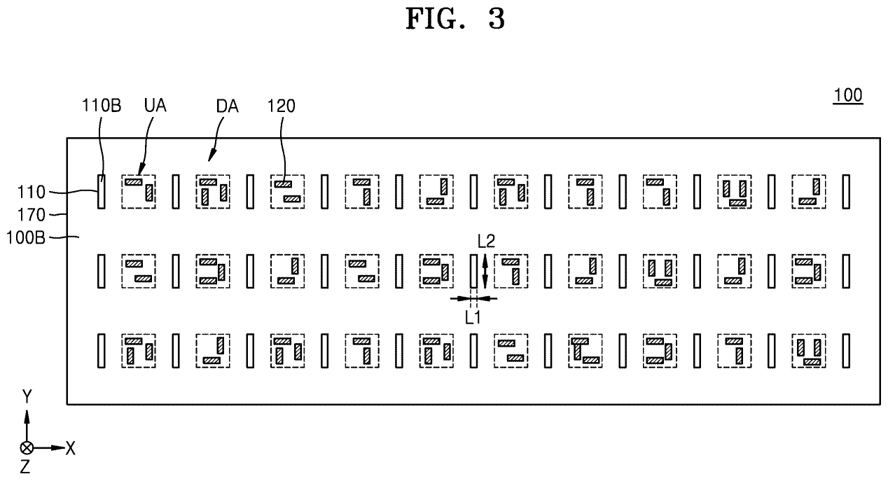

FIG. 1 is a cross-sectional view of a package substrate according to some embodiments. FIG. 2 is a schematic plan view of the package substrate of FIG. 1. FIG. 3 is a schematic bottom view of the package substrate of FIG. 1.

Referring to FIGS. 1 to 3, a package substrate 100 may include a body 190, an upper solder resist layer 150, and a lower solder resist layer 170.

The body 190 may include an upper surface and a lower surface opposite to the upper surface, and at least one of the upper surface and the lower surface thereof may be flat. The body 190 may include an insulating layer 110, a wiring pattern 130, an upper substrate pad 140, and a lower substrate pad 120. The insulating layer may be provided as at least one layer. According to some embodiments, the insulating layer 110 may be provided as a plurality of insulating layers stacked in one direction may be provided, and the wiring pattern 130 may penetrate the insulating layers 110 from the upper surface of the body 190 to the lower surface of the body 190. The wiring pattern 130 may function as an electrical connection path that penetrates the upper surface and the lower surface of the body 190. The wiring pattern 130 may electrically connect the upper substrate pad 140 to the lower substrate pad 120. The wiring pattern 130 may be formed inside the insulating layers 110.

In the following drawings, the direction in which the plurality of insulating layers 110 are stacked may be understood as a Z-axis direction, and an X-axis direction and a Y-axis direction may be defined as directions perpendicular to each other in a plane having the Z-axis direction as a normal vector. In the same sense, the X-axis direction and the Y-axis direction may represent directions parallel to the upper surface or the lower surface of body 190, and the X-axis direction and the Y-axis direction may be directions perpendicular to each other. The Z-axis direction may represent a direction perpendicular to the upper surface or the lower surface of the body 190, that is, a direction perpendicular to the X-Y plane. In addition, in the following drawings, a first horizontal direction, a second horizontal direction, and a vertical direction in the following drawings may be understood as follows. The first horizontal direction may be understood as the X-axis direction, the second horizontal direction may be understood as the Y-axis direction, and the vertical direction may be understood as the Z-axis direction.

According to some embodiments, the insulating layer 110 may be provided as three layers, but is not limited thereto. The insulating layer 110 may be provided as one, two, or four layers or more. Although the insulating layer 110 is illustrated as three layers in FIG. 1, this is merely an example and is not limited thereto.

The wiring pattern 130 may include a wiring via pattern 131 and a wiring line pattern 133. The wiring line pattern 133 may extend in the first horizontal direction (X-axis direction) within the insulating layers 110. According to some embodiments, the wiring line pattern 133 may be provided in one or more of the plurality of insulating layers 110 stacked in the vertical direction (Z-axis direction). The wiring via pattern 131 may extend in the vertical direction (Z-axis direction) and may penetrate at least one insulating layer 110 in the vertical direction (Z-axis direction). The wiring via pattern 131 may electrically connect the wiring line patterns 133 which are formed in different insulating layers 110, respectively.

In some embodiments, the wiring via pattern 131 may have a tapered shape in which a horizontal width of the wiring via pattern 131 increases from the bottom to the top thereof. That is, the wiring via pattern 131 may have a tapered shape in which the horizontal width of the wiring via pattern 131 increases as the vertical level thereof increases. For example, the wiring via pattern 131 may have a wider horizontal width as the wiring via pattern 131 approaches the upper solder resist layer 150, but is not limited thereto. In some embodiments, the wiring via pattern 131 may have a tapered shape in which the horizontal width of the wiring via pattern 131 increases as the level thereof in the vertical direction (Z-axis direction) decreases. For example, the wiring via pattern 131 may have a wider horizontal width as the wiring via pattern 131 approaches the lower solder resist layer 170.

The upper substrate pad 140 may be disposed on the upper surface of the body 190. A plurality of upper substrate pads 140 may be provided, and in some embodiments, the plurality of upper substrate pads 140 may be spaced apart from each other in the horizontal directions (X-axis and Y-axis directions) on the upper surface of the body 190. The upper substrate pad 140 may be exposed upward from the body 190 in the vertical direction (Z-axis direction). Specifically, an upper surface of the upper substrate pad 140 may be exposed upward from the insulating layer 110 in the vertical direction (Z-axis direction). The upper substrate pad 140 may be electrically connected to the wiring pattern 130.

The lower substrate pad 120 may be disposed on the lower surface of the body 190. A plurality of lower substrate pads 120 may be provided, and in some embodiments, the plurality of lower substrate pads 120 may be spaced apart from each other in the horizontal directions (X-axis and Y-axis directions) on the lower surface of the body 190. The lower substrate pad 120 may be exposed downward from the body 190 in the vertical direction (Z-axis direction). Specifically, the lower surface of the lower substrate pad 120 may be exposed downward from the insulating layer 110 in the vertical direction (Z-axis direction). The lower substrate pad 120 may be electrically connected to the wiring pattern 130.

The upper substrate pads 140 and/or the lower substrate pads 120 may be formed through a single plating process on a seed layer formed on the upper surface and the lower surface of the body 190. The upper substrate pads 140 and/or the lower substrate pads 120 may be conductive pads, for example, metal pads. More specifically, the upper substrate pads 140 and the lower substrate pads 120 may be, for example, a copper (Cu) pad, a nickel (Ni) pad or an aluminum (Al) pad plated with Ni, but is not limited thereto.

The upper solder resist layer 150 may cover the upper surface of the body 190. The upper solder resist layer 150 may cover the upper substrate pad 140 and the upper surface of the uppermost insulating layer 110. According to some embodiments, the upper surface of the upper solder resist layer 150 may be flat.

The lower solder resist layer 170 may cover the lower surface of the body 190. The lower solder resist layer 170 may cover the lower substrate pad 120 and the lower surface of the lowermost insulating layer 110. According to some embodiments, the lower solder resist layer 170 may expose at least a portion of the lower surface of the insulating layer 110 downward in the vertical direction (Z-axis direction). For example, at least a portion of the lower surface of the insulating layer 110 may be exposed downward in the vertical direction (Z-axis direction) through a recess RI formed in the lower solder resist layer 170.

The upper solder resist layer 150 and/or the lower solder resist layer 170 may be configured to mechanically protect the body 190 and prevent corrosion. The upper solder resist layer 150 and/or the lower solder resist layer 170 may include photo solder resist. According to some embodiments, the upper solder resist layer 150 and the lower solder resist layer 170 may include an acrylic-based resin, an epoxy-based resin, a urethane-based resin, a silicone-based resin, a para-xylene-based resin, a perylene-based resin, and the like. In addition, the upper solder resist layer 150 and the lower solder resist layer 170 may be formed by a method, such as dipping, spraying, flow coating, or vacuum coating.

According to some embodiments, the package substrate 100 may be a printed circuit board (PCB). In this case, the insulating layer 110 may include at least one material selected from a phenol resin, an epoxy resin, and a polyimide. The insulating layer 110 may include, for example, at least one material selected from flame retardant 4 (FR-4), tetrafunctional epoxy, polyethylene ether, epoxy/polyphenylene oxide, bismaleimide triazine (BT), Thermount (polyimide nonwoven aramid), cyanate ester, polyimide, and liquid crystal polymer. In addition, the wiring pattern 130 may include copper, nickel, stainless steel, or beryllium copper.

In some embodiments, the package substrate 100 may be a redistribution structure formed through a redistribution process. In this case, the insulating layer 110 may be formed from a photo-imageable dielectric (PID) or a photosensitive polyimide (PSPI), and the wiring pattern 130 may include, for example, a metal, such as Cu, Al, tungsten (W), titanium (Ti), tantalum (Ta), indium (In), molybdenum (Mo), manganese (Mn), cobalt (Co), tin (Sn), Ni, magnesium (Mg), rhenium (Re), beryllium (Be), gallium (Ga), ruthenium (Ru), or an alloy thereof, but is not limited thereto. In some embodiments, the wiring pattern 130 may be formed by laminating the metal or the alloy thereof on a seed layer including Cu, Ti, TiN, or TiW. According to some embodiments, the wiring line pattern 133 may be formed together with the wiring via pattern 131 to form an integrated structure.

The package substrate 100 may have an upper surface 100A and a lower surface 100B opposite to the upper surface 100A. The upper surface 100A of the package substrate 100 may be substantially the same as the upper surface of the upper solder resist layer 150. The lower surface 100B of the package substrate 100 may be defined as the lower surface of the lower solder resist layer 170 and the lower surface 110B of the insulating layer 110. A vertical level of the lower surface of the lower solder resist layer 170 may be lower than a vertical level of the lower surface 110B of the insulating layer 110.

The upper surface 100A and the lower surface 100B of the package substrate 100 may include a unit area UA and a dummy area DA. The unit area UA defined in the upper surface 100A of the package substrate 100 may be an area overlapping with the area in which the upper substrate pad 140 is formed in the vertical direction (Z-axis direction). According to some embodiments, the unit area UA defined in the upper surface 100A of the package substrate 100 may overlap with at least one upper substrate pad 140 in the vertical direction (Z-axis direction). A plurality of unit areas UA may be provided, and the plurality of unit areas UA may be spaced apart from each other in the horizontal directions (X-axis and Y-axis directions).

The dummy area DA defined in the upper surface 100A of the package substrate 100 may be an area excluding the unit area UA in the upper surface 100A of the package substrate 100. According to some embodiments, the dummy area DA defined in the upper surface 100A of the package substrate 100 may not overlap with the upper substrate pad 140 in the vertical direction (Z-axis direction).

The unit area UA defined in the lower surface 100B of the package substrate 100 may be an area overlapping with the area in which the lower substrate pad 120 is formed in the vertical direction (Z-axis direction). According to some embodiments, the unit area UA defined in the lower surface 100B of the package substrate 100 may overlap with at least one lower substrate pad 120 in the vertical direction (Z-axis direction). A plurality of unit areas UA may be provided, and the plurality of unit areas UA may be spaced apart from each other in the horizontal directions (X-axis and Y-axis directions).

The dummy area DA defined in the lower surface 100B of the package substrate 100 may be an area excluding the unit area UA in the lower surface 100B of the package substrate 100. According to some embodiments, the dummy area DA defined in the lower surface 100B of the package substrate 100 may not overlap with the lower substrate pad 120 in the vertical direction (Z-axis direction). The dummy area DA and the unit area UA which are defined in the upper surface 100A of the package substrate 100 may be understood as the dummy area DA and unit area UA which are defined in the upper solder resist layer 150, and the dummy area DA and the unit area UA which are defined in the lower surface 100B of the package substrate 100 may be understood as the dummy area DA and the unit area UA which are defined in the lower solder resist layer 170.

A recess R1 may be formed in the lower surface 100B of the package substrate 100. The recess R1 may be formed in an area defined as the dummy area DA in the lower surface 100B of the package substrate 100. The recess R1 as illustrated in FIG. 2 is not formed in an area defined as the unit area UA in the lower surface 100B of the package substrate 100.

The recess R1 may extend in the vertical direction (Z-axis direction) from the lower surface 100B of the package substrate 100 to the lower surface 110B of the insulating layer 110. The lower surface 110B of the insulating layer 110 may be exposed downward from the lower solder resist layer 170 in the vertical direction (Z-axis direction) by the recess R1. According to some embodiments, the depth T1 of the recess R1 in the vertical direction (Z-axis direction) may be in a range of about 10 um to about 15 um. In the same sense, the distance between the lower surface 110B of the insulating layer 110 and the lower surface 100B of the package substrate 100 in the vertical direction (Z-axis direction) may be in a range of about 10 um to about 15 um. The thickness of the lower solder resist layer 170 in the vertical direction (Z-axis direction) may be in a range of about 10 um to about 15 um.

As shown in FIG. 3, the recess R1 may be formed to have a longitudinal direction parallel to a short axis of the package substrate 100. For example, a side of the package substrate 100 extending in the first horizontal direction (X-axis direction) may be a long axis, and a side of the package substrate 100 extending in the second horizontal direction (Y-axis direction) may be a short axis. In this case, the recess R1 formed in the lower surface 100B of the package substrate 100 may have a longitudinal direction in the second horizontal direction (Y-axis direction), which is the short-axis direction of the package substrate 100. That is, the recess R1 formed in the lower surface 100B of the package substrate 100 may extend in the second horizontal direction (Y-axis direction), which is the short-axis direction of the package substrate 100. The cross-section of the recess R1 formed in the lower surface 100B of the package substrate 100 in the X-Y plane may have a rectangular shape extending in the second horizontal direction (Y-axis direction). However, the cross-section of the recess R1 formed in the lower surface 100B of the package substrate 100 in the X-Y plane is not limited thereto.

According to some embodiments, the cross-section of the recess R1 formed in the lower surface 100B of the package substrate 100 in the X-Z plane may have a rectangular shape. For example, a sidewall 100C of the recess R1 may be perpendicular to the lower surface 110B of the insulating layer 110.

According to some embodiments, the length L1 of the recess R1 formed in the lower surface 100B of the package substrate 100 in the first horizontal direction (X-axis direction) may be in a range of about 150 um to about 250 um. The length L2 of the recess R1 formed in the lower surface 100B of the package substrate 100 in the second horizontal direction (Y-axis direction) may be in a range of about 10 mm to about 15 mm. That is, a long side of the cross-section of the recess R1 in the X-Y plane may be in a range of about 10 mm to about 15 mm, and a short side of the cross-section of the recess R1 in the X-Y plane may also be in a range of about 150 um to about 250 um.

A plurality of recesses R1 may be formed in the lower surface 100B of the package substrate 100. The plurality of recesses R1 may be spaced apart from each other in the horizontal directions (X-axis and Y-axis directions). The plurality of recesses R1 may extend along the side surfaces of the unit area UA of the lower surface 100B of the package substrate 100 in the first horizontal direction (X-axis direction). For example, both sides of one unit area UA of the lower surface 100B of the package substrate 100 in the first horizontal direction (X-axis direction) may each face the recess R1. As can be seen in FIG. 3, the wiring patterns within each UA unit areas have a length in the Y direction, which length can be similar or substantially the same as the length L2 of each R1 recess, such that the R1 recesses are substantially disposed in areas between the UA unit areas within the rows of UA unit areas in the X direction.

In some embodiments, the recess R1 may not be formed in the upper surface 100A of the package substrate 100.

The package substrate 100 may include the upper solder resist layer 150 covering the body 190 and the lower solder resist layer 170. In addition, the recess R1 passing through the lower solder resist layer 170 in the vertical direction (Z-axis direction) may be formed in the lower solder resist layer 170.

As the recess R1 is formed in the lower solder resist layer 170, a ratio of the upper solder resist layer 150 on the upper surface 100A of the package substrate 100 to the lower solder resist layer 170 on the lower surface 100B of the package substrate 100 may be greater than 1. The ratio may be understood as at least one of a mass ratio and a volume ratio. In the package substrate 100, when the ratio of the upper solder resist layer 150 to the lower solder resist layer 170 is greater than 1, the warpage of the package substrate 100 may be improved.

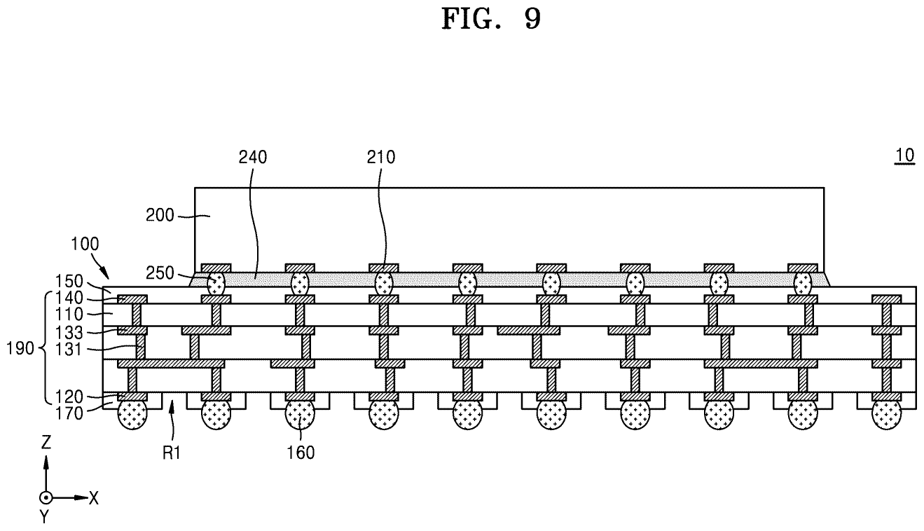

As the recess R1 is formed in the lower solder resist layer 170, the warpage of the package substrate 100 may be prevented, thereby minimizing a non-wet failure in which the upper substrate pad 140 located in the center area of the package substrate 100 is not in contact with a bump 250 (see FIG. 9) when bonding semiconductor chips to the package substrate 100.

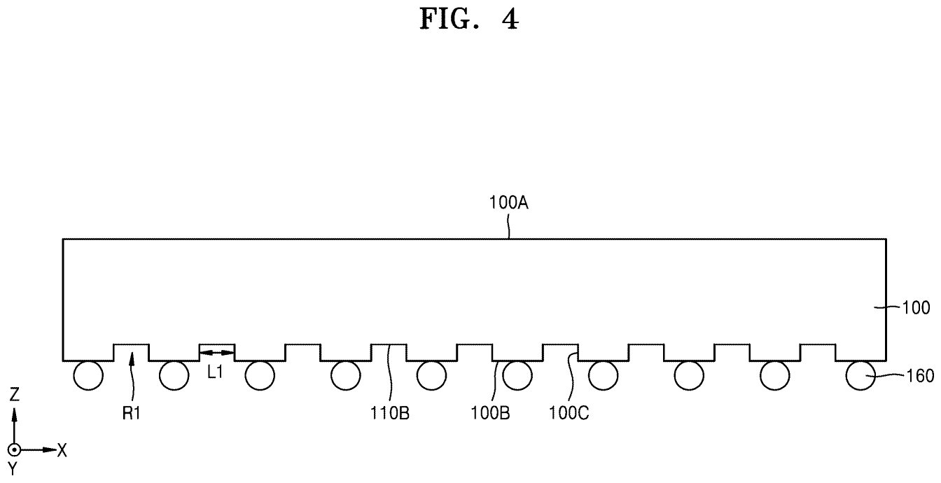

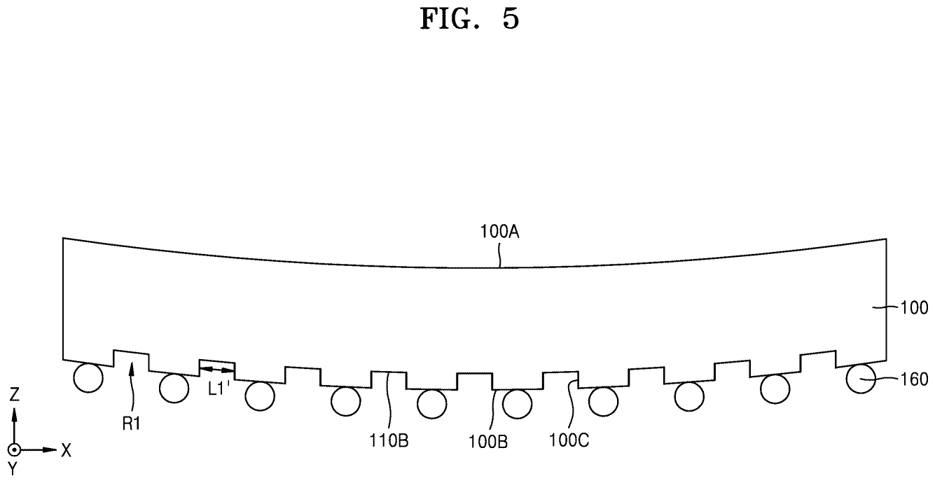

FIGS. 4 and 5 are cross-sectional views illustrating the warpage of the package substrate 100 of FIG. 1. In the following description, the overlapping contents described with reference to FIGS. 1 to 3 are omitted.

Referring to FIGS. 4 and 5, a recess R1 may be formed in the lower surface 100B of the package substrate 100. According to some embodiments, a plurality of recesses R1 may be provided. The lower surface 110B of the insulating layer 110 may be exposed downward in the vertical direction (Z-axis direction) by the recess R1.

An external connection bump 160 may be located in an area in which the recess R1 is not formed in the lower surface 100B of the package substrate 100. The external connection bump 160 may be located below the package substrate 100. The external connection bump 160 may be electrically connected to an external device, for example, a motherboard. The external connection bump 160 may be electrically connected to the wiring pattern 130. The external connection bump 160 may transmit an electrical signal received from the wiring pattern 130 to the external device. The wiring pattern 130 may be electrically connected to the external device through the external connection bump 160. The external connection bump 160 may include a conductive material, for example, at least one of solder, Sn, silver (Ag), Cu, and Al.

As shown in FIG. 4, when the package substrate 100 is not exposed to at least one of a high temperature and a high pressure environment, that is, before a warpage occurs in the package substrate 100, the package substrate 100 may have a rectangular shape having a longitudinal direction in the first horizontal direction (X-axis direction).

However, as shown in FIG. 5, when the package substrate 100 is exposed to at least one of a high temperature and a high pressure environment, the warpage occurs in the package substrate 100, and a central portion of the package substrate 100 may be deformed to be located at a vertical level lower than an edge portion of the package substrate 100. That is, the package substrate 100 may be warped such that the central portion of the package substrate 100 faces downward in the vertical direction (Z-axis direction), and the edge portion of the package substrate 100 faces upward in the vertical direction (Z-axis direction). It may be understood that the warpage of the package substrate 100 occurs as the lower surface 100B of the package substrate 100 expands more than the upper surface 100A of the package substrate 100.

The package substrate 100 may include a recess R1 formed in the lower surface 100B of the package substrate 100. If the lower surface 100B of the package substrate 100 expands due to a high-temperature or high-pressure environment, the length of the recess R1 in the first horizontal direction (X-axis direction) may decrease, thereby decreasing the warpage of the package substrate 100.

When the lower surface 100B of the package substrate 100 expands, the lower surface 100B of the package substrate 100 may expand in a direction in which the length of the recess R1 in the first horizontal direction (X-axis direction) decreases. For example, the length L1′ of the recess R1 in the first horizontal direction (X-axis direction), shown in FIG. 5, when the package substrate 100 is exposed to a high temperature or high pressure environment and a warpage occurs may be less than the length L1 of the recess R1 in the first horizontal direction (X-axis direction), shown in FIG. 4, before the package substrate 100 is exposed to the high temperature or high pressure environment. That is, the horizontal width of the lower surface 110B of the insulating layer 110 in FIG. 5 may be less than that in FIG. 4.

Accordingly, the total length over which the lower surface 100B of the package substrate 100 expands when the recess R1 is formed in the lower surface 100B of the package substrate 100 may be less than that when the recess R1 is not formed in the lower surface 100B of the package substrate 100.

In addition, the recess R1 formed in the lower surface 100B of the package substrate 100 may have a longitudinal direction in the second horizontal direction (Y-axis direction), which is a short-axis direction of the package substrate 100. Accordingly, when the lower surface 100B of the package substrate 100 extends in the first horizontal direction (X-axis direction), the area of the recess R1 functioning as a buffer may increase.

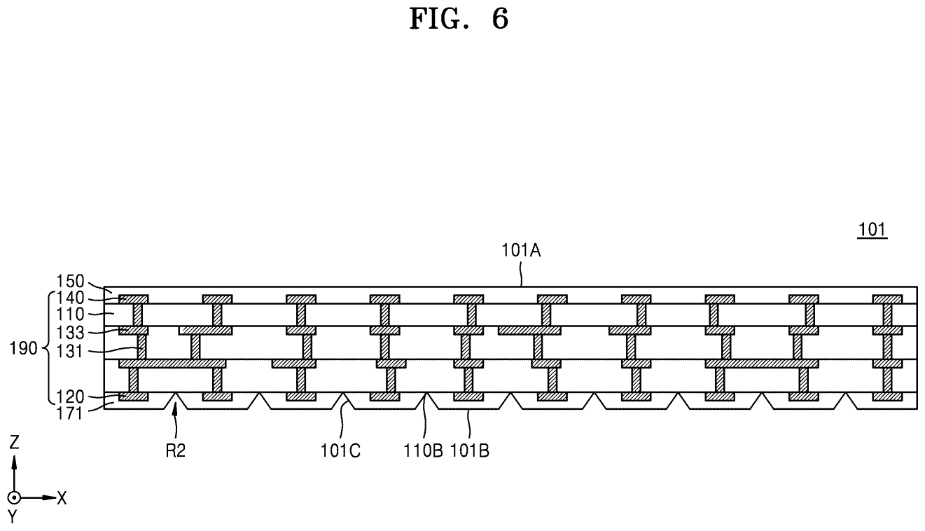

FIG. 6 is a schematic cross-sectional view of a package substrate according to some embodiments. Hereinafter, overlapping contents between the package substrate 100 described with reference to FIGS. 1 to 5 and a package substrate 101 of FIG. 6 are omitted, and description is made focusing on differences therebetween.

Referring to FIG. 6, the package substrate 101 may include a body 190, an upper solder resist layer 150, and a lower solder resist layer 171. The body 190 may include an insulating layer 110, a wiring pattern 130, an upper substrate pad 140, and a lower substrate pad 120. The wiring pattern 130 may include a wiring via pattern 131 and a wiring line pattern 133. The upper substrate pad 140 may be disposed on an upper surface of the body 190. The lower substrate pad 120 may be disposed on a lower surface of the body 190.

The upper solder resist layer 150 may cover the upper surface of the body 190. The upper solder resist layer 150 may cover the upper substrate pad 140 and the upper surface of the uppermost insulating layer 110. According to some embodiments, the upper surface of the upper solder resist layer 150 may be flat.

The lower solder resist layer 171 may cover the lower surface of the body 190. The lower solder resist layer 171 may cover the lower substrate pad 120 and the lower surface of the lowermost insulating layer 110. According to some embodiments, the lower solder resist layer 171 may expose at least a portion of the lower surface 110B of the insulating layer 110 downward in the vertical direction (Z-axis direction). For example, at least a portion of the lower surface 110B of the insulating layer 110 may be exposed downward in the vertical direction (Z-axis direction) through a recess R2 formed in the lower solder resist layer 171.

The package substrate 101 may have an upper surface 101A and a lower surface 101B opposite to the upper surface 110A. The upper surface 101A of the package substrate 101 may be substantially the same as the upper surface of the upper solder resist layer 150. The lower surface 101B of the package substrate 101 may be defined as the lower surface of the lower solder resist layer 171 and the lower surface 110B of the insulating layer 110. A vertical level of the lower surface of the lower solder resist layer 171 may be lower than a vertical level of the lower surface 110B of the insulating layer 110.

The upper surface 101A and the lower surface 101B of the package substrate 101 may include a unit area UA and a dummy area DA. The unit area UA defined in the upper surface 101A of the package substrate 101 may be an area overlapping with the area in which the upper substrate pad 140 is formed in the vertical direction (Z-axis direction). According to some embodiments, the unit area UA defined in the upper surface 101A of the package substrate 101 may overlap with at least one upper substrate pad 140 in the vertical direction (Z-axis direction). A plurality of unit areas UA may be provided, and the plurality of unit areas UA may be spaced apart from each other in the horizontal directions (X-axis and Y-axis directions).

The dummy area DA defined in the upper surface 101A of the package substrate 101 may be an area excluding the unit area UA in the upper face 101A of the package substrate 101. According to some embodiments, the dummy area DA defined in the upper surface 101A of the package substrate 101 may not overlap with the upper substrate pad 140 in the vertical direction (Z-axis direction).

The unit area UA defined in the lower surface 101B of the package substrate 101 may be an area overlapping with the area in which the lower substrate pad 120 is formed in the vertical direction (Z-axis direction). According to some embodiments, the unit area UA defined in the lower surface 101B of the package substrate 101 may overlap with at least one lower substrate pad 120 in the vertical direction (Z-axis direction). A plurality of unit areas UA may be provided, and the plurality of unit areas UA may be spaced apart from each other in the horizontal directions (X-axis and Y-axis directions).

The dummy area DA defined in the lower surface 101B of the package substrate 101 may be an area excluding the unit area UA in the lower surface 101B of the package substrate 101. According to some embodiments, the dummy area DA defined in the lower surface 101B of the package substrate 101 may not overlap with the lower substrate pad 120 in the vertical direction (Z-axis direction).

The recess R2 may be formed in the lower surface 101B of the package substrate 101. The recess R2 may be formed in an area defined as the dummy area DA in the lower surface 101B of the package substrate 101. The recess R2 may not be formed in an area defined as the unit area UA in the lower surface 101B of the package substrate 101.

The recess R2 may extend in the vertical direction (Z-axis direction) from the lower surface 101B of the package substrate 101. According to some embodiments, the cross-section of the recess R2 in the X-Z plane may have a triangular shape. The cross-section of the recess R2 in the X-Z plane may have a tapered shape in which the horizontal width of the recess R2 decreases as the vertical level thereof increases. A sidewall 101C of the recess R2 may form an obtuse angle with the lower surface 101B of the package substrate 101. In some embodiments, the lower surface 110B of the insulating layer 110 exposed downward in the vertical direction (Z-axis direction) by the recess R2 may have a line shape extending in the second horizontal direction (Y-axis direction).

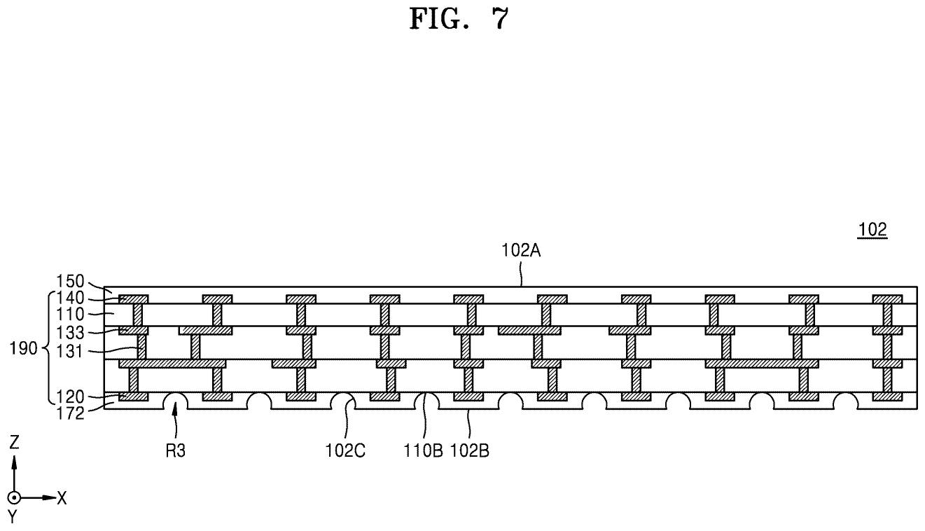

FIG. 7 is a schematic cross-sectional view of a package substrate according to some embodiments. Hereinafter, overlapping contents between the package substrate 100 described with reference to FIGS. 1 to 5 and a package substrate 102 of FIG. 7 are omitted, and description is made focusing on differences therebetween.

Referring to FIG. 7, the package substrate 102 may include a body 190, an upper solder resist layer 150, and a lower solder resist layer 172. The body 190 may include an insulating layer 110, a wiring pattern 130, an upper substrate pad 140, and a lower substrate pad 120. The wiring pattern 130 may include a wiring via pattern 131 and a wiring line pattern 133. The upper substrate pad 140 may be disposed on an upper surface of the body 190. The lower substrate pad 120 may be disposed on a lower surface of the body 190.

The upper solder resist layer 150 may cover the upper surface of the body 190. The upper solder resist layer 150 may cover the upper substrate pad 140 and the upper surface of the uppermost insulating layer 110. According to some embodiments, the upper surface of the upper solder resist layer 150 may be flat.

The lower solder resist layer 172 may cover the lower surface of the body 190. The lower solder resist layer 172 may cover the lower substrate pad 120 and the lower surface of the lowermost insulating layer 110. According to some embodiments, the lower solder resist layer 172 may expose at least a portion of the lower surface 110B of the insulating layer 110 downward in the vertical direction (Z-axis direction). For example, at least a portion of the lower surface 110B of the insulating layer 110 may be exposed downward in the vertical direction (Z-axis direction) by a recess R3 formed in the lower solder resist layer 172.

The package substrate 102 may have an upper surface 102A and a lower surface 102B opposite to the upper surface 102A. The upper surface 102A of the package substrate 102 may be substantially the same as the upper surface of the upper solder resist layer 150. The lower surface 102B of the package substrate 102 may be defined as the lower surface of the lower solder resist layer 172 and the lower surface 110B of the insulating layer 110. A vertical level of the lower surface of the lower solder resist layer 172 may be lower than a vertical level of the lower surface 110B of the insulating layer 110.

The upper surface 102A and the lower surface 102B of the package substrate 102 may include a unit area UA and a dummy area DA. The unit area UA defined in the upper surface 102A of the package substrate 102 may be an area overlapping with the area in which the upper substrate pad 140 is formed in the vertical direction (Z-axis direction). According to some embodiments, the unit area UA defined in the upper surface 102A of the package substrate 102 may overlap with at least one upper substrate pad 140 in the vertical direction (Z-axis direction). A plurality of unit areas UA may be provided, and the plurality of unit areas UA may be spaced apart from each other in the horizontal directions (X-axis and Y-axis directions).

The dummy area DA defined in the upper surface 102A of the package substrate 102 may be an area excluding the unit area UA in the upper surface 102A of the package substrate 102. According to some embodiments, the dummy area DA defined in the upper surface 102A of the package substrate 102 may not overlap with the lower substrate pad 120 in the vertical direction (Z-axis direction).

The unit area UA defined in the lower surface 102B of the package substrate 102 may be an area overlapping with the area in which the lower substrate pad 120 is formed in the vertical direction (Z-axis direction). According to some embodiments, the unit area UA defined in the lower surface 102B of the package substrate 102 may overlap with at least one lower substrate pad 120 in the vertical direction (Z-axis direction). A plurality of unit areas UA may be provided, and the plurality of unit areas UA may be spaced apart from each other in the horizontal directions (X-axis and Y-axis directions).

The dummy area DA defined in the lower surface 102B of the package substrate 102 may be an area excluding the unit area UA in the lower surface 102B of the package substrate 102. According to some embodiments, the dummy area DA defined in the lower surface 102B of the package substrate 102 may not overlap with the lower substrate pad 120 in the vertical direction (Z-axis direction).

The recess R3 may be formed in the lower surface 102B of the package substrate 102. The recess R3 may be formed in an area defined as the dummy area DA in the lower surface 102B of the package substrate 102. The recess R3 may not be formed in an area defined as the unit area UA in the lower surface 102B of the package substrate 102.

The recess R3 may extend in the vertical direction (Z-axis direction) from the lower surface 102B of the package substrate 102. According to some embodiments, the cross-section of the recess R3 in the X-Z plane may have a circular shape. The cross-section of the recess R3 in the X-Z plane may include a curve. A sidewall 102C of the recess R3 may have a curved shape.

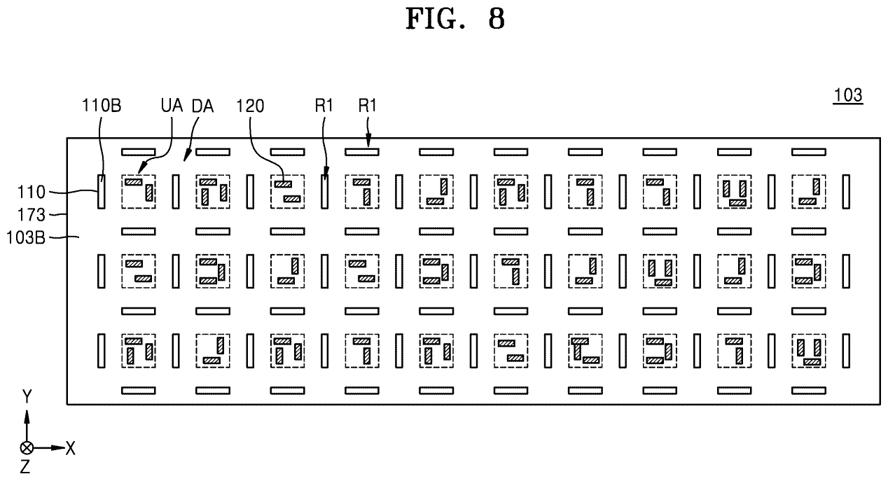

FIG. 8 is a schematic bottom view of a package substrate 103 according to some embodiments. Hereinafter, overlapping contents between the package substrate 100 described with reference to FIGS. 1 to 5 and the package substrate 103 of FIG. 8 are omitted, and description is made focusing on differences therebetween.

Referring to FIG. 8, a lower surface 103B of the package substrate 103 may be defined as a lower surface of a lower solder resist layer 173 and the lower surface 110B of the insulating layer 110. A vertical level of the lower surface of the lower solder resist layer 173 may be lower than a vertical level of the lower surface 110B of the insulating layer 110.

The lower surface 103B of the package substrate 103 may include a unit area UA and a dummy area DA. The unit area UA defined in the lower surface 103B of the package substrate 103 may be an area overlapping with the area in which the lower substrate pad 120 is formed in the vertical direction (Z-axis direction). According to some embodiments, the unit area UA defined in the lower surface 103B of the package substrate 103 may overlap with at least one lower substrate pad 120 in the vertical direction (Z-axis direction). A plurality of unit areas UA may be provided, and the plurality of unit areas UA may be spaced apart from each other in the horizontal directions (X-axis and Y-axis directions).

The dummy area DA defined in the lower surface 103B of the package substrate 103 may be an area excluding the unit area UA in the lower surface 103B of the package substrate 103. According to some embodiments, the dummy area DA defined in the lower surface 103B of the package substrate 103 may not overlap with the lower substrate pad 120 in the vertical direction (Z-axis direction).

A recess R1 may be formed in the lower surface 103B of the package substrate 103. The recess R1 may be formed in an area defined as the dummy area DA in the lower surface 103B of the package substrate 103. The recess R1 may not be formed in an area defined as the unit area UA in the lower surface 103B of the package substrate 103.

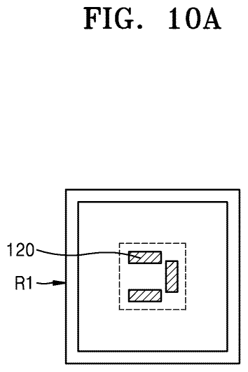

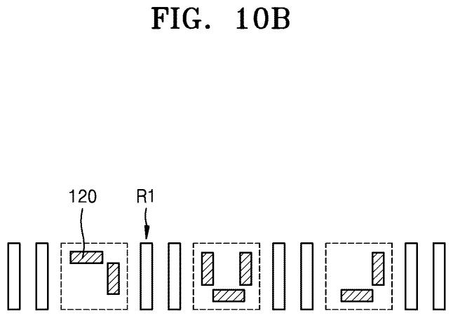

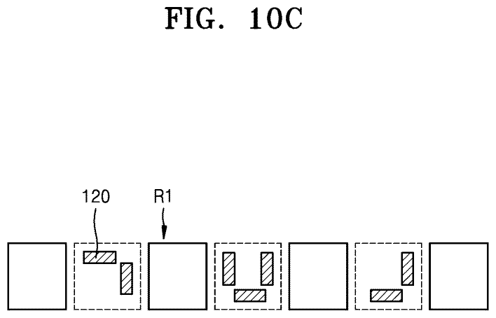

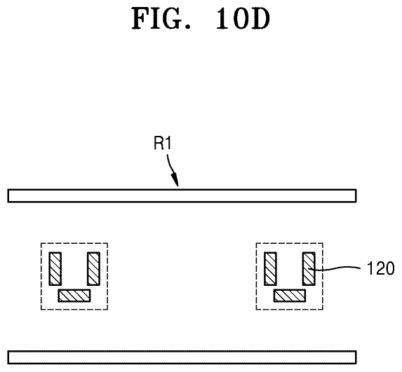

The recess R1 may extend in the vertical direction (Z-axis direction) from the lower surface 103B of the package substrate 103. A plurality of recesses R1 may be provided. The plurality of recesses R1 may surround the unit area UA defined in the lower surface 103B of the package substrate 103 in the X-Y plane. For example, the recess R1 may be formed on each of the first horizontal direction (X-axis direction) side and the second horizontal direction (Y-axis direction) side of the unit area UA defined in the lower surface 103B of the package substrate 103. As can be seen in FIG. 8, some recesses R1 can extend as elongated grooves in the X direction whereas other recesses R1 can extend as elongated grooves in the Y direction. Alternatively, the recesses R1 can be formed as “moats” fully surrounding respective unit areas UA (FIG. 10A) or multiple recesses (e.g., grooves or canals) can be formed between unit areas UA (FIG. 10B). And the shape of the recesses R1 as viewed in the Z direction can be other than an elongated groove shape, and can be a square or other polygonal shape in between unit areas UA (FIG. 10C). The recesses can be formed between unit areas UA in the X direction and/or between unit areas UA in the Y direction (FIG. 10D).

FIG. 9 is a schematic cross-sectional view of a semiconductor package according to some embodiments. In the following description, the overlapping contents described with reference to FIGS. 1 to 8 are omitted.

Referring to FIG. 9, a semiconductor package 10 may include a package substrate 100, a bump 250, a semiconductor chip 200, a semiconducting chip pad 210, and an underfill material layer 240.

The semiconductor chip 200 may be mounted on an upper surface of the package substrate 100. The semiconductor chip 200 may be electrically connected to the wiring pattern 130. According to some embodiments, the semiconductor chip 200 may be mounted on the package substrate 100 in a flip chip manner through the bump 250, such as a micro-bump. According to some embodiments, the underfill material layer 240 surrounding the bump 250 may be positioned between the semiconductor chip 200 and the package substrate 100. The underfill material layer 240 may include, for example, an epoxy resin formed by a capillary underfill method. However, in some embodiments, the gap between the semiconductor chip 200 and the package substrate 100 may be directly filled through a molded underfill process, such as EMC. In this case, the underfill material layer 240 may be omitted.

The semiconductor chip 200 may include a memory chip or a logic chip. The memory chip may include, for example, a volatile memory chip, such as dynamic random access memory (DRAM) or static random access memory (SRAM), or a non-volatile memory chip, such as phase-change random access memory (PRAM), magneto-resistive random access memory (MRAM), ferroelectric random access memory (FeRAM), or resistive random access memory (RRAM). The logic chip may include, for example, a microprocessor, such as a central processing unit (CPU), a graphics processing unit (GPU), or an application processor (AP), an analog device, or a digital signal processor.

Although one semiconductor chip 200 mounted on the package substrate 100 is shown in FIG. 9, a plurality of semiconductor chips 200 may be mounted on the package substrate 100. In addition, the semiconductor package 10 may include a 2.5D package including an interposer substrate, a 3D package in which the plurality of semiconductor chips 200 are stacked in the vertical direction (Z-axis direction), and the like.

While the inventive concept has been particularly shown and described with reference to embodiments thereof, it will be understood that various changes in form and details may be made therein without departing from the spirit and scope of the following claims.

What is claimed is:

1. A package substrate comprising:
a body including at least one insulating layer stacked in a vertical direction and wiring patterns located in the insulating layer;
an upper solder resist layer covering an upper surface of the body; and
a lower solder resist layer covering a lower surface of the body,
wherein the upper surface of the body is sealed by the upper solder resist layer, and
wherein a recess is formed in the lower solder resist layer exposing at least a portion of the lower surface of the body.

2. The package substrate of claim 1, wherein a depth of the recess in the vertical direction is in a range of about 10 um to about 15 um.

3. The package substrate of claim 1, wherein a cross-section of the recess in the X-Y plane has a longitudinal direction parallel to a short axis of the body.

4. The package substrate of claim 3, wherein a long side of the cross-section of the recess in the X-Y plane is in a range of about 10 mm to about 15 mm, and a short side of the cross-section of the recess in the X-Y plane is in a range of about 150 um to about 250 um.

5. The package substrate of claim 1, wherein a cross-section of the recess in the X-Z plane has a rectangular shape.

6. The package substrate of claim 1, wherein a sidewall of the recess forms an obtuse angle with a lower surface of the lower solder resist layer.

7. The package substrate of claim 1, wherein a cross-section of the recess in the X-Z plane includes a curved line.

8. The package substrate of claim 1, further comprising an upper substrate pad exposed upward from the body in the vertical direction, and a lower substrate pad exposed downward from the body in the vertical direction.

9. The package substrate of claim 8, wherein a unit area defines an area that overlaps with the upper substrate pad of the upper solder resist layer in the vertical direction, and a dummy area defines an area that does not overlap with the upper substrate pad in the vertical direction, and
wherein the unit area overlaps with the lower substrate pad of the lower solder resist layer in the vertical direction, and the dummy area does not overlap with the lower substrate pad in the vertical direction.

10. The package substrate of claim 9, wherein the recess is formed in the dummy area of the lower solder resist layer.

11. The package substrate of claim 1, wherein a semiconductor chip is mounted on the upper solder resist layer using a flip chip method.

12. A semiconductor package comprising:
a package substrate;
a semiconductor chip positioned on the package substrate; and
a bump positioned between the package substrate and the semiconductor chip,
wherein the package substrate comprises:
a body comprising at least one insulating layer stacked in a vertical direction and wiring patterns located in the insulating layer;
an upper solder resist layer covering an upper surface of the body; and
a lower solder resist layer covering a lower surface of the body, wherein the upper surface of the body is sealed by the upper solder resist layer and the lower solder resist layer has a recess that extends in the vertical direction.

13. The semiconductor package of claim 12, wherein a cross-section of the recess in a plane of the lower solder resist layer has a longitudinal direction parallel to a short axis of the body.

14. The semiconductor package of claim 12, wherein a cross-section of the recess in a plane orthogonal to a plane of the lower solder resist layer has a triangular shape.

15. The semiconductor package of claim 12, wherein a cross-section of the recess in a plane orthogonal to a plane of the lower solder resist layer has a circular shape.

16. The semiconductor package of claim 12, further comprising an underfill material layer surrounding the bump.

17. The semiconductor package of claim 12, wherein the recess surrounds a unit area in a plane of the lower solder resist layer.

18. A semiconductor package comprising:
a package substrate;
a semiconductor chip positioned on the package substrate; and
a bump positioned between the package substrate and the semiconductor chip,
wherein the package substrate comprises:
a body comprising at least one insulating layer stacked in a vertical direction and wiring patterns located in the insulating layer;
an upper substrate pad located on an upper surface of the body;
a lower substrate pad located on a lower surface of the body;
an upper solder resist layer covering the upper surface of the body; and
a lower solder resist layer covering the lower surface of the body,
wherein the lower solder resist layer comprises a unit area that overlaps with the lower substrate pad in the vertical direction, and a dummy area that does not overlap with the lower substrate pad in the vertical direction,
the upper surface of the body is sealed by the upper solder resist layer,
the lower solder resist layer has a recess extending in the vertical direction,
the recess is formed in the dummy area, and
a cross-section of the recess in the X-Y plane has a longitudinal direction parallel to a short axis of the body.

19. The semiconductor package of claim 18, wherein the depth of the recess in the vertical direction is in a range of about 10 um to about 15 um, and a long side of the cross-section of the recess in the X-Y plane is in a range of about 10 mm to about 15 mm, and
a short side of the cross-section of the recess in the X-Y plane is in a range of about 150 um to about 250 um.

20. The semiconductor package of claim 18, wherein the recess surrounds the unit area in the X-Y plane.
